(19) United States
(12) Patent Application Publication
(10) Pub. No.: US 2024/0139967 A1
(43) Pub. Date: May 2, 2024

(54) SUBSTRATE TRANSPORT ROBOT AND SUBSTRATE PROCESSING SYSTEM INCLUDING THE SAME

(71) Applicant: SEMES CO., LTD., Chungcheongnam-do (KR)

(72) Inventors: Sang Hyeop LEE, Gyeonggi-do (KR); Ki Won HAN, Gyeonggi-do (KR); Sang Oh KIM, Seoul (KR); Kyo Bong KIM, Gyeonggi-do (KR); Hee Chan KIM, Gyeonggi-do (KR)

(21) Appl. No.: 18/384,639

(22) Filed: Oct. 27, 2023

(30) Foreign Application Priority Data
Oct. 31, 2022 (KR) 10-2022-0142483

(51) Int. Cl. B25J 11/00; B25J 9/16; B25J 13/08; B25J 15/00

(52) U.S. Cl. CPC B25J 11/0095; B25J 9/1682; B25J 13/088; B25J 15/0014

(57) ABSTRACT

A substrate transport robot capable of enhancing processing speed and avoiding interference with structures and a system including the substrate transport robot are provided. The substrate transport robot includes: one or more robot arms including transfer hands and transferring semiconductor substrates with the transfer hands; an arm driving module coupled to each of the robot arms and controlling the movement of each of the robot arms; and a horizontal/vertical movement module controlling the position movement of the arm driving module, wherein multiple robot arms are provided, and multiple transfer hands are included in each of the multiple robot arms.

### CROSS-REFERENCE TO RELATED APPLICATION

This application claims priority from Korean Patent Application No. 10-2022-0142483 filed on Oct. 31, 2022 in the Korean Intellectual Property Office, and all the benefits accruing therefrom under 35 U.S.C. 119, the contents of which in its entirety are herein incorporated by reference.

### BACKGROUND

### 1. Field

The present disclosure relates to a substrate transport robot and a substrate processing system including the same, and more particularly, a substrate transport robot, which is used in semiconductor manufacturing processes, and a substrate processing system including the substrate transport robot.

### 2. Description of the Related Art

Semiconductor manufacturing processes may be performed continuously within semiconductor manufacturing equipment and may be divided into front-end and back-end processes. The front-end process refers to the process of forming circuit patterns on a wafer to complete semiconductor chips, while the back-end process refers to the process of evaluating the performance of the finished products from the front-end process.

Semiconductor manufacturing equipment may be installed within semiconductor fabrication facilities, known as “fabs,” to manufacture semiconductors. Wafers may undergo various processes such as deposition, photolithography, etching, polishing, ion implantation, cleaning, packaging, and testing, each required for semiconductor production and may be transferred by a wafer transport robot to the equipment where the respective processes are to be performed.

The wafer transport robot consists of one arm and two hands and performs pick-and-place operations through the individual driving of the arm and the hands. However, the wafer transport robot's processing speed is significantly slow due to using both hands for the transfer of wafers.

Moreover, during avoidance motions, there is a risk of collision between the ends of the hands and both sidewalls of an equipment front end module (EFEM), necessitating additional space for prevention.

### SUMMARY

Aspects of the present disclosure provide a substrate transport robot capable of enhancing processing speed and avoiding interference with structures and a substrate processing system including the substrate transport robot.

However, aspects of the present disclosure are not restricted to those set forth herein. The above and other aspects of the present disclosure will become more apparent to one of ordinary skill in the art to which the present disclosure pertains by referencing the detailed description of the present disclosure given below.

According to an aspect of the present disclosure, a substrate transport robot includes: one or more robot arms including transfer hands and transferring semiconductor substrates with the transfer hands; an arm driving module coupled to each of the robot arms and controlling the movement of each of the robot arms; and a horizontal/vertical movement module controlling the position movement of the arm driving module, wherein multiple robot arms are provided, and multiple transfer hands are included in each of the multiple robot arms.

According to another aspect of the present disclosure, a substrate transport robot includes: one or more robot arms including transfer hands and transferring semiconductor substrates with the transfer hands; an arm driving module coupled to each of the robot arms and controlling the movement of each of the robot arms; and a horizontal/vertical movement module controlling the position movement of the arm driving module, wherein multiple robot arms are provided, multiple transfer hands are included in each of the multiple robot arms, the multiple robot arms and the multiple transfer hands are arranged in a height direction of the substrate transport robot, the multiple robot arms serve different purposes, the multiple transfer hands include a first transfer hand, which operates independently, and a plurality of transfer hands, which operate simultaneously, a position of a single transfer hand that operates independently varies from one robot hand to another robot hand among the multiple transfer hands included in each of the multiple robot arms, the multiple transfer hands include transfer hands that are used in pick-and-place operations for the semiconductor substrates and transfer hands that are not used in the pick-and-place operations, and the transfer hands not used in the pick-and-place operations rotate in at least one of clockwise and counterclockwise directions based on distances to both walls.

According to another aspect of the present disclosure, a substrate processing system includes: load port modules providing mounting surfaces for containers loaded with semiconductor substrates; load lock chambers temporarily storing the semiconductor substrates and switching into one of an atmospheric environment and a vacuum environment depending on whether the semiconductor wafers are being loaded or unloaded; process chambers processing the semiconductor substrates; an index module operating at the atmospheric environment and transferring the semiconductor substrates between the load port modules and the load lock chambers; and a transfer chamber operating at the vacuum environment and transferring the semiconductor substrates between the load lock chambers and the process chambers, wherein a substrate transport robot is provided within the index module and includes one or more robot arms, which include transfer arms and transfer the semiconductor substrates using the transfer hands, an arm driving module, which is coupled to each of the robot arms and controls the movement of each of the robot arms, and a horizontal/vertical movement module, which controls the position movement of the arm driving module, multiple robot arms are provided, and multiple transfer hands are included in each of the multiple robot arms.

It should be noted that the effects of the present disclosure are not limited to those described above, and other effects of the present disclosure will be apparent from the following description.

### BRIEF DESCRIPTION OF THE DRAWINGS

The above and other aspects and features of the present disclosure will become more apparent by describing in detail exemplary embodiments thereof with reference to the attached drawings, in which:

FIGS. 1, 2, and 3 are first, second, and third exemplary schematic views, respectively, illustrating the internal structure of a substrate processing system including a substrate transport robot;

FIG. 4 is a schematic view illustrating the structure of the substrate transport robot, which is installed in an index module of the substrate processing system;

FIGS. 5 and 6 are a side view and a front view, respectively, illustrating the arrangement of the robot arms and the transfer hands of the substrate transport robot according to a first exemplary embodiment of the present disclosure;

FIG. 7 is a front view illustrating the arrangement of the robot arms and the transfer hands of the substrate transport robot according to a second exemplary embodiment of the present disclosure;

FIGS. 8, 9, and 10 are first, second, and third exemplary schematic views, respectively, illustrating an operating method of a robot arm with multiple transfer hands;

FIGS. 11 and 12 are a side view and a front view, respectively, illustrating the arrangement of the robot arms and the transfer hands of the substrate transport robot according to a third exemplary embodiment of the present disclosure;

FIGS. 13, 14, and 15 are first, second, and third exemplary schematic views, respectively, illustrating a method of avoiding interference between a structure and a substrate transport robot with multiple robot arms and multiple transfer hands;

FIGS. 16 and 17 are first and second exemplary schematic views, respectively, illustrating an obstacle detection method for a substrate transport robot with multiple robot arms and multiple transfer hands.

### DETAILED DESCRIPTION

Embodiments of the present disclosure will hereinafter be described with reference to the accompanying drawings. Like reference numerals indicate like elements throughout the present disclosure, and thus, redundant descriptions thereof will be omitted.

The present disclosure pertains to a substrate transport robot, which is used in semiconductor manufacturing processes and can improve processing speed and enable avoidance of interference with structures, and a substrate processing system including the substrate transport robot.

The substrate processing system treats semiconductor substrates according to various processes and may be implemented as semiconductor manufacturing equipment. The substrate processing system including the substrate transport robot will hereinafter be described.

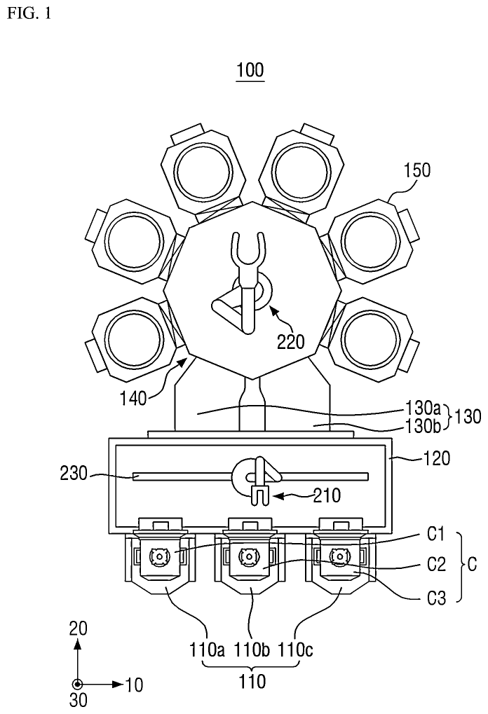

FIGS. 1, 2, and 3 are first, second, and third exemplary schematic views, respectively, illustrating the internal structure of a substrate processing system including a substrate transport robot.

Referring to FIGS. 1 through 3, a substrate processing system 100 may be configured to include load port modules 110, an index module 120, load lock chambers 130, a transfer chamber 140, and process chambers 150.

The substrate processing system 100 may treat or process semiconductor substrates through various processes such as deposition, etching, cleaning, heat treatment, and photolithography. The substrate processing system 100 may be provided as a multi-chamber substrate processing system, including multiple substrate transport robots, which are for transporting substrates, and multiple process chambers, which surround the substrate transport robots.

The load port modules 110 are where containers C are loaded or unloaded. Additionally, semiconductor substrates stored in the containers C may also be loaded or unloaded within the load port modules 110. The load port modules 110 may be provided at the ends of front end modules (FEMs), such as equipment FEMs (EFEMs) or semi-FEMs (SFEMs).

In the containers C, multiple semiconductor substrates may be stored. The containers C may be provided, for example, as front opening unified pods (FOUPs), and the semiconductor substrates may be, for example, wafers.

The containers C may be loaded into or unloaded from the load port modules 110 by a container transport unit. The container transport unit may load the containers C into the load port modules 110 by mounting the containers C on the load port modules 110, and may unload the containers C from the load port modules 110 by gripping the containers C placed on the load port modules 110. The container transport unit is for transporting the containers C to their destination and may be provided as, for example, an overhead hoist transporter (OHT).

Semiconductor wafers may be loaded into or unloaded from the containers C mounted on the load port modules 110 by a substrate transport robot 210 in the index module 120. Once the containers C are mounted on the load port modules 110, the substrate transport robot 210 may approach the load port modules 110 and retrieve the semiconductor substrates from the containers C. In this manner, the unloading of semiconductor substrates may be performed.

On the other hand, when the processing of semiconductor substrates in the process chambers 150 are complete, the substrate transport robot 110 may retrieve the semiconductor substrates from the load lock chambers 130 and place the received semiconductor substrates back into the containers C. In this manner, the loading of semiconductor substrates may be performed.

As mentioned earlier, the load port modules 110 may be provided to accommodate the containers C with multiple semiconductor substrates loaded therein. The load port modules 110 may be configured to include a plurality of load ports, which are arranged at the front of the index module 120. For example, three load port modules, i.e., first, second, and third load port modules 110a, 110b, and 110c, may be arranged at the front of the index module 120.

In a case where multiple load port modules are arranged at the front of the index module 120, containers C mounted on the respective load port modules may load different types of objects. For example, if the first, second, and third load port modules 110a, 110b, and 110c are provided at the front of the index module 120, a first container C1 mounted on the first load port module 110a may load wafer-type sensors, a second container C2 mounted on the second load port module 110b may load semiconductor substrates (or wafers), and a third container C3 mounted on the third load port module 110c may load consumables such as focus rings.

However, the present disclosure is not limited to this. Alternatively, the first, second, and third containers C1, C2, and C3, which are mounted on different load ports, i.e., on the first, second, and third load port modules 110a, 110b, and 110c, respectively, may be configured to load the same type of objects. Yet alternatively, some of the first, second, and third containers C1, C2, and C3 may load the same type of objects, and the other container(s) may load a different type of objects.

The index module 120 is disposed between the load port modules 110 and the load lock chambers 130 and serves as an interface for transferring semiconductor substrates between the load lock chambers 130 and the containers C on the load port modules 110. As described earlier, the load port modules 110 and the index module 120 may be provided as FEMs.

The index module 120 may include the substrate transport robot 210, which is for transferring substrates. The substrate transport robot 210 operates under atmospheric pressure and may transfer semiconductor substrates between the load port modules 110 and the load lock chambers 130.

The load lock chambers 130 may function as buffers between input and output ports of the substrate processing system 100. Although not explicitly illustrated in FIGS. 1 through 3, the load lock chambers 130 may include buffer stages where semiconductor substrates are temporarily stored.

Multiple load lock chambers 130 may be disposed between the index module 120 and the transfer chamber 140. For example, two load lock chambers, i.e., first and second load lock chambers 130a and 130b, may be disposed between the index module 120 and the transfer chamber 140.

The first and second load lock chambers 130a and 130b may be arranged in a direction parallel to the direction of the arrangement of the first, second, and third load port modules 110a, 110b, and 110c between the index module 120 and the transfer chamber 140, i.e., in a first direction 10. In this case, the first and second load lock chambers 130a and 130b may be provided into a symmetrical single-layer structure where the first and second load lock chambers 130a and 130b are arranged side-by-side in a lateral direction.

However, the present disclosure is not limited to this. The first and second load lock chambers 130a and 130b may be arranged in a direction perpendicular to the direction in which the first, second, and third load port modules 110a, 110b, and 110c are arranged between the index module 120 and the transfer chamber 140, i.e., in a third direction 30. In this case, the first and second load lock chambers 130a and 130b may be provided into a multilayer structure where the first and second load lock chambers 130a and 130b are arranged vertically.

The first load lock chamber 130a may transfer semiconductor substrates from the index module 120 to the transfer chamber 140, and the second load lock chamber 130b may transfer semiconductor substrates from the transfer chamber 140 to the index module 120. However, the present disclosure is not limited to this. Alternatively, the first load lock chamber 130a may transfer semiconductor substrates from the transfer chamber 140 to the index module 120 and from the index module 120 to the transfer chamber 140, and the second load lock chamber 130b may transfer semiconductor substrates from the transfer chamber 140 to the index module 120 and from the index module 120 to the transfer chamber 140.

Semiconductor wafers may be loaded into or unloaded from the load lock chambers 130 by a substrate transport robot 220 in the transfer chamber 140. Furthermore, semiconductor wafers may be loaded into or unloaded from the load lock chambers 130 by the substrate transport robot 210 in the index module 120. For convenience, the substrate transport robot 210, which is provided within the index module 120, is defined as the first transport robot 210, and the substrate transport robot 220, which is provided within the transfer chamber 140, is defined as the second transport robot 220.

The load lock chambers 130 may maintain pressure by changing its internal environment between a vacuum environment and an atmospheric environment using gate valves. In this manner, the load lock chambers 130 may prevent changes in the internal pressure state of the transfer chamber 140.

Specifically, when substrates are loaded or unloaded by the second transport robot 220, the load lock chambers 130 may be configured with an internal environment similar to or the same as the vacuum environment of the transfer chamber 140. Likewise, when substrates are loaded or unloaded by the first transport robot 210 (i.e., when unprocessed substrates are loaded or processed substrates are unloaded), the load lock chambers 130 may be configured with an internal environment similar to or the same as the atmospheric pressure environment of the index module 120.

The transfer chamber 140, which is also referred to as a transfer module (TM), transports substrates between the load lock chambers 130 and the process chambers 150. For this purpose, the transfer chamber 140 may include at least one second transport robot 220.

The second transport robot 220 transfers unprocessed substrates from the load lock chambers 130 to the process chambers 150 or processed substrates from the process chamber 150 to the load lock chambers 130. The sides of the transfer chamber 140 may be connected to the load lock chambers 130 and the process chambers 150. The second transport robot 220 may operate in a vacuum environment and may be rotatably provided.

The process chambers 150 process semiconductor substrates. Multiple process chambers 150 may be arranged around the transfer chamber 140. In this case, the process chambers 150 may receive semiconductor substrates from the transfer chamber 140, process the received semiconductor substrates, and provide the processed semiconductor substrates back to the transfer chamber 140.

The process chambers 150 may be chambers of the same type or different types, selected from among various types of chambers such as a chamber for a deposition process, a chamber for an etching process, a chamber for a cleaning process, a chamber for a heat treatment process, and a chamber for a photolithography process.

The process chambers 150 may be formed in a cylindrical shape. The process chambers 150 may be formed of alumina with a surface coated with an anodic oxide film (or alumite) and may be configured in a sealed manner internally. However, the process chambers 150 may be formed in various other shapes than a cylindrical shape.

The substrate processing system 100 may be formed in a cluster platform structure, as illustrated in FIG. 1. In this case, the transfer chamber 140 may have a polygonal or circular shape, and multiple process chambers 150 may be arranged in a clustered manner around the transfer chamber 140.

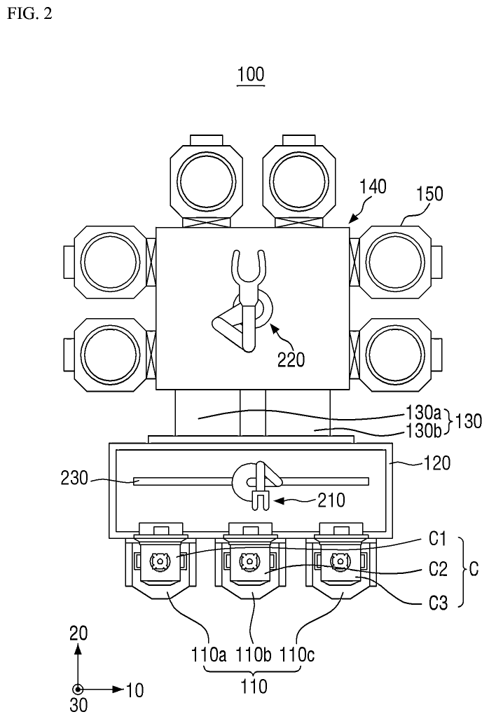

However, the present embodiment is not limited to this. Alternatively, the substrate processing system 100 may be formed in a quad platform structure, as illustrated in FIG. 2. In this case, the transfer chamber 140 may have a square shape, and multiple process chambers 150 may be arranged in a quad manner around the transfer chamber 140.

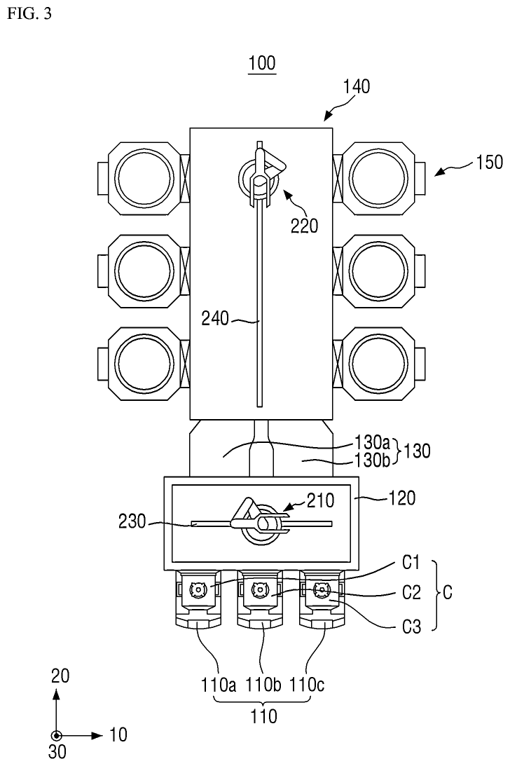

Alternatively, the substrate processing system 100 may be formed in an inline platform structure, as illustrated in FIG. 3. In this case, the transfer chamber 140 may have a rectangular shape, and multiple process chambers 150 may be arranged in a row on both sides of the transfer chamber 140.

Although not explicitly illustrated in FIGS. 1 through 3, the substrate processing system 100 may be operated by a controller. The controller may include a process controller, which consists of a microprocessor (or a computer) that executes control of each of a plurality of modules (110, 120, 130, 140, and 150) in the substrate processing system 100, a user interface, which includes a keyboard for an operator to input commands and manage the modules (110, 120, 130, 140, and 150) and a display to visualize and display the operational status of each of the modules (110, 120, 130, 140, and 150), and a memory unit, which stores control programs for executing processes under the control of the process controller or programs (or processing recipes) for executing processes in the modules (110, 120, 130, 140, and 150) based on various data and processing conditions. The user interface and the memory unit may be connected to the process controller. The processing recipes may be stored on a storage medium within the memory unit, such as a hard disk, a CD-ROM, a DVD, or a flash memory.

Thereafter, the substrate transport robot 210 in the index module 120, i.e., the first transport robot 210, will hereinafter be described.

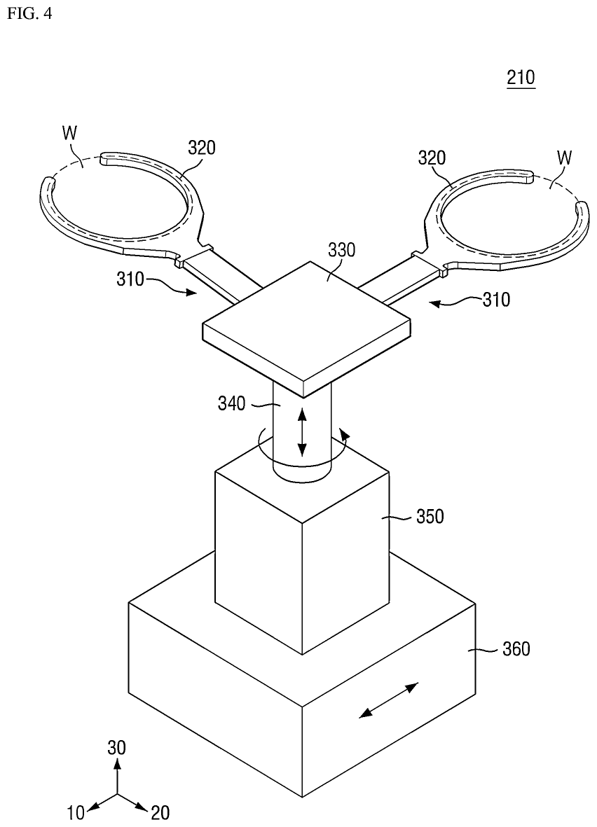

FIG. 4 is a schematic view illustrating the structure of the substrate transport robot, which is installed in an index module of the substrate processing system.

Referring to FIG. 4, the substrate transfer robot 210 may include robot arms 310, transfer hands 320, an arm driving module 330, a rotation module 340, a vertical movement module 350, and a horizontal movement module 360.

The index module 120 may include one or more guide rails 230, as illustrated in FIGS. 1 through 3. The guide rails 230 may provide a moving path for the substrate transfer robot 210.

A single guide rail 230 may be provided within the index module 120. In this case, the guide rail 230 may be arranged in a longitudinal direction (e.g., the first direction 10) parallel to the direction of the arrangement of the first, second, and third load port modules 110a, 110b, and 110c within the index module 120.

However, the present disclosure is not limited to this. Alternatively, a plurality of guide rails 230 may be provided within the index module 120. In this case, the rails 230 may be provided to intersect one another, and some of the rails 230 may be arranged in the longitudinal direction (e.g., the first direction 10) parallel to the direction of the arrangement of the first, second, and third load port modules 110a, 110b, and 110c within the index module 120, while other rails 230 may be arranged in a longitudinal direction (e.g., a second direction 20) perpendicular to the direction of the arrangement of the first, second, and third load port modules 110a, 110b, and 110c within the index module 120. The configuration of the guide rail(s) 230 is not particularly limited and may vary depending on a variety of factors such as the number of substrate transfer robots 210, the operating range of the robot arms 310 of the substrate transfer robot 210, the number and locations of load port modules 110, and the number and locations of load lock chambers 130.

One or more guide rails 240 may also be provided in the transfer chamber 140, as illustrated in FIG. 3. In this case, the guide rails 240 may provide a moving path for the substrate transport robot 220 with in the transfer chamber 140.

The robot arms 310 may retrieve unprocessed semiconductor substrates from the containers C on the load port modules 110 and transfer the retrieved unprocessed semiconductor substrates to the load lock chambers 130. Alternatively, the robot arms 310 may retrieve already-processed semiconductor substrates from the load lock chambers 130 and transfer the retrieved processed semiconductor substrates to the containers C on the load port modules 110.

The robot arms 310 may be coupled to the arm driving module 330 and may move horizontally in a longitudinal direction (e.g., the second direction 20) according to the operation of the arm driving module 330. Additionally, the robot arms 310 may rotate horizontally in the lateral direction (e.g., the first direction 10) according to the operation of the arm driving module 330.

Multiple robot arms 310 may be provided on the arm driving module 330. For example, the robot arms 310 include two arms, i.e., first and second robot arms 310a and 310b. The number of robot arms 310 may increase or decrease depending on the process efficiency of the substrate processing system 100.

The transfer hands 320, which provide mounting surfaces for semiconductor substrates W, may be disposed at the ends of the robot arms 310. Multiple transfer hands 320 may be provided on the robot arms 310, and each of the transfer hands 320 may handle one substrate. The transfer hands 320 may be provided in the form of, for example, end effectors.

The arm driving module 330 horizontally moves the robot arms 310. The robot arms 310 may be installed on the sides of the arm driving module 330, but the present disclosure is not limited thereto. Alternatively, the robot arms 310 may be installed on the top surface of the arm driving module 330. Alternatively, some of the robot arms 310 may be installed on the sides of the arm driving module 330, while the other robot arms 310 may be installed on the upper surface of the arm driving module 330.

The rotation module 340 may be installed below the arm driving module 330 and may be coupled to the arm driving module 330. The rotation module 340 enables the arm driving module 330 to rotate, and as a result, the robot arms 310 may rotate accordingly.

However, the present disclosure is not limited to this. Alternatively, the arm driving module 330 may be configured to enable the robot arms 310 to move or rotate horizontally, in which case, the substrate transport robot 210 may not include the rotation module 240.

The vertical movement module 350 elevates the rotation module 340 in the height direction (e.g., the third direction 30) of the substrate transfer robot 210. As a result, the positions of the robot arms 310 and the transfer hands 320 in the vertical direction (e.g., the third direction 30) within the index module 110 may be adjusted. The vertical movement module 350 may be installed below the rotation module 340.

Although not explicitly illustrated in FIG. 4, the horizontal movement module 360 may be coupled to the guide rails 230 and may move horizontally along the guide rails 230. As a result, the positions of the robot arms 310 and the transfer hands 320 in the horizontal direction (e.g., the first direction 10) within the index module 110 may be adjusted. The horizontal movement module 360 may be installed below the vertical movement module 350. The vertical movement module 350 and the horizontal movement module 360 may be integrated into a single horizontal/vertical movement module.

The structure of the substrate transport robot 210 has been described so far with reference to FIG. 4. The substrate transport robot 210 may be provided on a linear motor (LM) guide system. The LM guide system may include LM rails or LM motors, in which case, the guide rails 230 may be provided as the LM rails, while the LM motors may be provided within the horizontal movement module 360.

To enhance the process efficiency of the substrate processing system 100, the substrate transfer robot 210 may include multiple robot arms 310 and multiple transfer hands 320. In this case, each of the robot arms 310 may include multiple transfer hands 320. The substrate transport robot 210 may be provided as, for example, a selective compliance assembly robot arm (SCARA) robot.

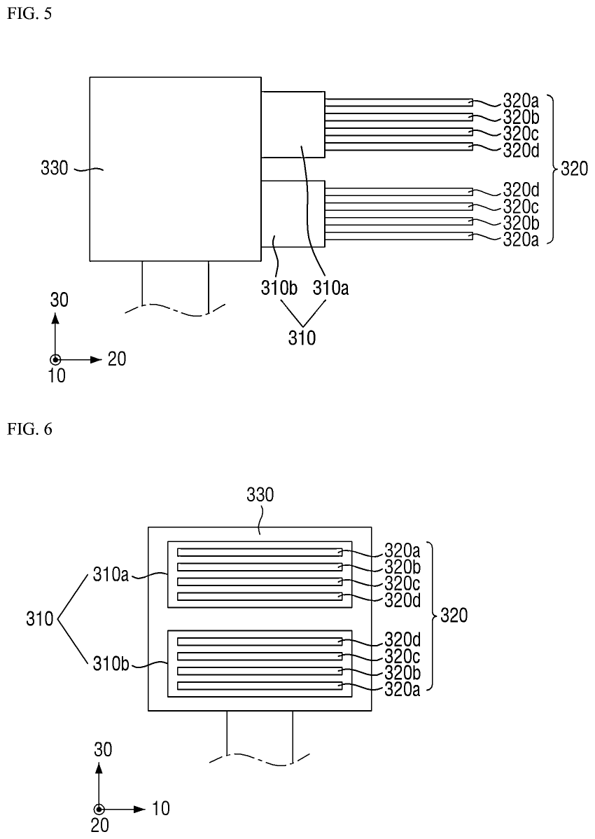

FIGS. 5 and 6 are a side view and a front view, respectively, illustrating the arrangement of the robot arms and the transfer hands of the substrate transport robot according to a first exemplary embodiment of the present disclosure.

A conventional substrate transport robot includes one arm and two hands and may perform a pick-and-place operation by driving each of the arm and the hands. Here, the pick-and-place operation refers to a series of processes of gripping semiconductor substrates and transferring the semiconductor substrates to their destinations.

However, the conventional substrate transport robot performs the transfer of substrates using one hand and two hands, resulting in a very slow processing speed, and it is not possible to configure clean and dirty hands to differentiate between pre-processing and post-processing.

On the contrary, the substrate transport robot 210 may include multiple robot arms 310, and each of the robot arms 310 may include a plurality of transfer hands 320. Therefore, the substrate transport robot 210 can improve the processing speed compared to the conventional substrate transport robot, and can perform tasks by separating the transfer hands 320 into clean hands for pre-processing and dirty hands for post-processing.

The substrate transport robot 210 will hereinafter be described as having, for example, two robot arms 310, each having four transfer hands 320. However, the number of robot arms 310 and/or the number of transfer hands 320 is not particularly limited. Furthermore, various structures for the robot arms 310 and the transfer hands 320 that will be presented below can be similarly applied or adapted in other cases.

The robot arms 310, which are installed in the substrate transport robot 210, may include two robot arms, i.e., the first and second robot arms 310a and 310b. The transfer hands 320, which are installed in each of the first and second robot arms 310a and 310b, may include four hands, i.e., first, second, third, and fourth transfer hands 320a, 320b, 320c, and 320d.

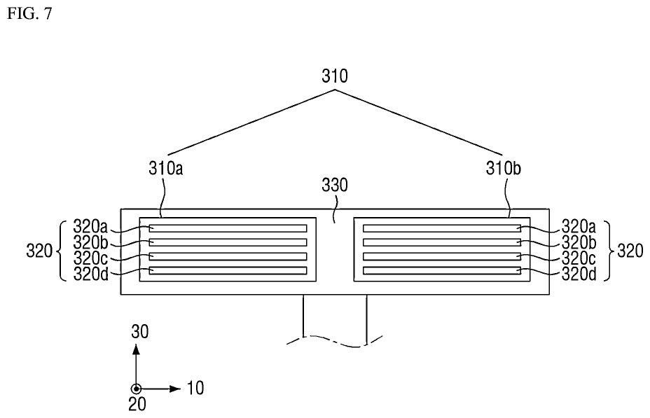

The first and second robot arms 310a and 310b may be arranged in the height direction (e.g., the third direction 30) of the substrate transport robot 210, but the present disclosure is not limited thereto. Alternatively, as illustrated in FIG. 7, the first and second robot arms 310a and 310b may be arranged in the lateral direction (e.g., the first direction 10) of the substrate transport robot 210. FIG. 7 is a front view illustrating the arrangement of the robot arms and the transfer hands of the substrate transport robot according to a second exemplary embodiment of the present disclosure.

Alternatively, the first and second robot arms 310a and 310b may be arranged diagonally with respect to each other, one on the upper side and the other on the lower side. As long as there are no difficulties in the simultaneous operation of the first and second robot arms 310a and 310b, the substrate transport robot 210 can be formed in any configuration, not limited to the arrangements illustrated in FIGS. 6 and 7.

Referring again to FIGS. 5 and 6, the first and second robot arms 310a and 310b may serve different purposes. For example, the first robot arm 310a, positioned relatively higher, may be used for a clean purpose, and the second robot arm 310b, positioned relatively lower, may be used for a dirty purpose. The clean purpose refers to the transfer of processed semiconductor substrates W. That is, the first robot arm 310a may transfer semiconductor substrates W on the containers C on the load port modules 110 within the load lock chambers 130. On the other hand, the dirty purpose refers to the transfer of unprocessed semiconductor substrates W. In this case, the second robot arm 310b may transfer semiconductor substrates W from the containers C on the load port modules 110 to the load lock chambers 130.

However, the present disclosure is not limited to this. The first robot arm 310a, positioned relatively higher, may be utilized for the dirty purpose, while the second robot arm 310b, positioned relatively lower, can be designated for the clean purpose. Alternatively, both the first and second robot arms 310a and 310b can be used for both the clean and dirty purposes simultaneously.

As previously mentioned, the first robot arm 310a may include four transfer hands, i.e., first, second, third, and fourth transfer hands 320a, 320b, 320c, and 320d. For convenience, the first, second, third, and fourth transfer hands 320a, 320b, 320c, and 320d of the first robot arm 310a will hereinafter be referred to simply as the first, second, third, and fourth transfer hands 320a, 320b, 320c, and 320d, respectively.

The first robot hand 320a is positioned at the top among the four transfer hands of the first robot arm 310a. The second transfer hand 320b is positioned below the first transfer hand 320a, the third transfer hand 320c is positioned below the second transfer hand 320b, and the fourth transfer hand 320d is positioned below the third transfer hand 320c. In other words, the fourth transfer hand 320d is at the bottom among the four transfer hands of the first robot arm 310a.

The first, second, third, and fourth transfer hands 320a, 320b, 320c, and 320d may be arranged in the height direction (e.g., the third direction 30) of the substrate transport robot 210, but the present disclosure is not limited thereto. Alternatively, if there is no difficulty in simultaneous operation, the first, second, third, and fourth transfer hands 320a, 320b, 320c, and 320d may also be arranged in the lateral direction (e.g., the first direction 10) of the substrate transport robot 210. Alternatively, some of the first, second, third, and fourth transfer hands 320a, 320b, 320c, and 320d may be arranged in the height direction of the substrate transport robot 210, while the other transfer hands may be arranged in the lateral direction of the substrate transport robot 210.

The second, third, and fourth transfer hands 320b, 320c, and 320d may operate simultaneously. Conversely, the first transfer hand 320a may operate separately from the second, third, and fourth transfer hands 320b, 320c, and 320d. That is, the first transfer hand 320a, unlike the second, third, and fourth transfer hands 320b, 320c, and 320d, may operate independently. By enabling an independent operation of the first transfer hand 320a, which is positioned at the outermost, interference with any structures can be avoided during avoidance motions.

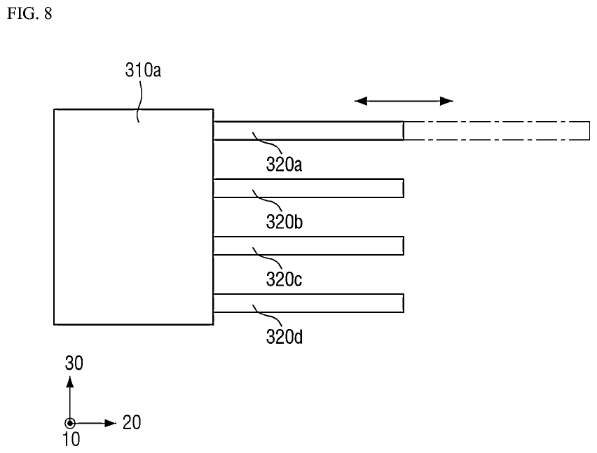

Only one of the first, second, third, and fourth transfer hands 320a, 320b, 320c, and 320d may be needed to transfer substrates W. For example, as illustrated in FIG. 8, the first transfer hand 320a may be used to transfer substrates W, and the second, third, and fourth transfer hands 320b, 320c, and 320d may be in idle state. FIG. 8 is a first exemplary schematic view illustrating an operating method of a robot arm with multiple transfer hands.

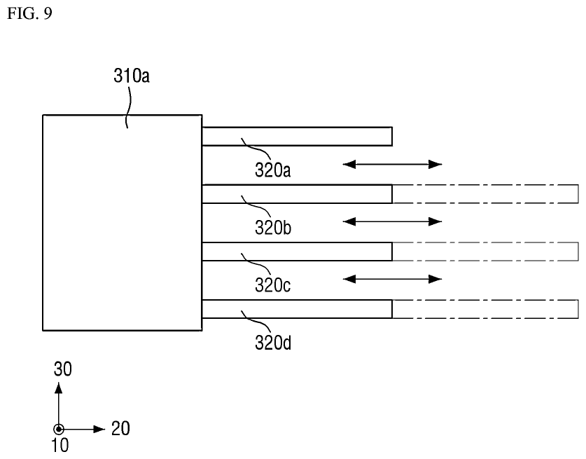

Alternatively, three of the first, second, third, and fourth transfer hands 320a, 320b, 320c, and 320d may be needed to transfer substrates W. For example, as illustrated in FIG. 9, the second, third, and fourth transfer hands 320b, 320c, and 320d may be used to transfer substrates W, and the first transfer hand 320a may be in idle state. FIG. 9 is a second exemplary schematic view illustrating the operating method of the robot arm with multiple transfer hands.

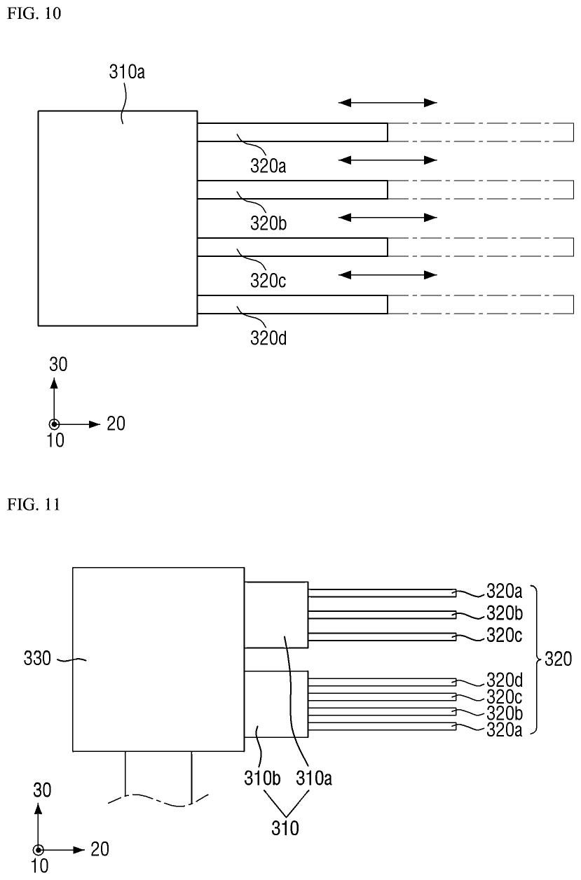

Alternatively, all the first, second, third, and fourth transfer hands 320a, 320b, 320c, and 320d may be needed to transfer substrates W. For example, as illustrated in FIG. 10, the first, second, third, and fourth transfer hands 320a, 320b, 320c, and 320d may all be used to transfer substrates W. FIG. 10 is a third exemplary schematic view illustrating the operating method of the robot arm with multiple transfer hands.

The second, third, and fourth transfer hands 320b, 320c, and 320d have been described as operating simultaneously, and the first transfer hand 320a has been described as operating independently from the other transfer hands. However, the present disclosure is not limited to this. Alternatively, all the four transfer hands of the first robot arm 310a may operate independently. In this case, it is possible to achieve effective handling for various scenarios, including cases where one transfer hand is needed for the transport of substrates W, where three transfer hands are needed for the transport of substrates W, cases where all four transfer hands are needed for the transport of substrates W, and even cases where only two transfer hands are needed.

For the cases where only two transfer hands are needed, one of the second, third, and fourth transfer hands 320b, 320c, and 320d may operate independently along with the first transfer hand 320a, while the remaining two transfer hands may operate simultaneously. For example, the first and second transfer hands 320a and 320b may operate independently, while the third and fourth transfer hands 320c and 320d may operate simultaneously.

The first, second, third, and fourth transfer hands 320a, 320b, 320c, and 320d may be used for the same purpose. For example, the first, second, third, and fourth transfer hands 320a, 320b, 320c, and 320d may be used for the clean purpose. Alternatively, the first, second, third, and fourth transfer hands 320a, 320b, 320c, and 320d may be used for the dirty purpose.

However, the present disclosure is not limited to this. Alternatively, as described earlier, the first, second, third, and fourth transfer hands 320a, 320b, 320c, and 320d may be used for different purposes. The first robot arm 310a may be used for both the clean and dirty purposes at the same time. In this case, some of the first, second, third, and fourth transfer hands 320a, 320b, 320c, and 320d may be used for the clean purpose, and the other transfer hands may be used for the dirty purpose. For example, the first transfer hand 320a may be used for the clean purpose, and the second, third, and fourth transfer hands 320b, 320c, and 320d may be used for the dirty purpose.

The second robot arm 310b, like the first robot arm 310a, may include four transfer hands, i.e., first, second, third, and fourth transfer hands 320a, 320b, 320c, and 320d. The following description will focus on the first, second, third, and fourth transfer hands 320a, 320b, 320c, and 320d of the second robot arm 310b, emphasizing the differences compared to those of the first robot arm 310a. Therefore, it should be understood that the description for the four transfer hands of the first robot arm 310a can be directly applied to the four transfer hands of the second robot arm 310b for all other aspects.

The first transfer hand 320a of the second robot arm 310b is positioned at the bottom among the four transfer hands of the second robot arm 310b. The second transfer hand 320b of the second robot arm 310b is positioned above the first transfer hand 320a of the second robot arm 310b, the third transfer hand 320c of the second robot arm 310b is positioned above the second transfer hand 320b of the second robot arm 310b, and the fourth transfer hand 320d of the second robot arm 310b is positioned above the third transfer hand 320c of the second robot arm 310b. In other words, the fourth transfer hand 320d of the second robot arm 310b is positioned at the top among the four transfer hands of the second robot arm 310b.

In the explanations of FIG. 5 and FIG. 6, both the first and second robot arms 310a and 310b include four transfer hands each. That is, the first robot arm 310a and the second robot arm 310b may have the same number of transfer hands. However, the present disclosure is not limited to this. Alternatively, the first and second robot arms 310a and 310b may include different numbers of transfer hands.

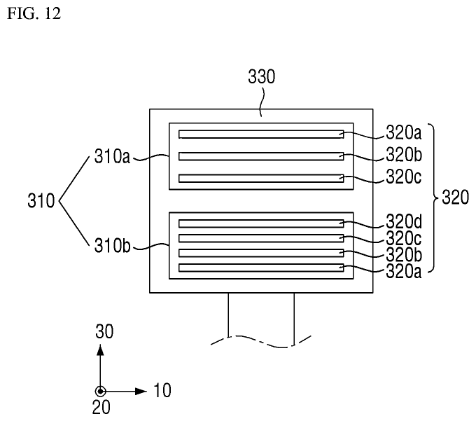

For example, as illustrated in FIGS. 11 and 12, the first robot arm 310a may include three transfer hands, i.e., first, second, and third transfer hands 320a, 320b, and 320c, and the second robot arm 310b may include four transfer hands, i.e., first, second, third, and fourth transfer hands 320a, 320b, 320c, and 320d. In this case, the first robot arm 310a may be positioned above the second robot arm 310b, and the three transfer hands of the first robot arm 310a may be used for the clean purpose, while the four transfer hands of the second robot arm 310b may be used for the dirty purpose.

The substrate processing system 100 includes multiple process chambers 150, and when the process chambers 150 perform different types of substrate processing operations, the substrate processing time may vary between the process chambers 150. For example, when one of the process chambers 150 performs an etching process and another one of the process chambers 150 performs a cleaning process, the amount of time that it takes to complete the etching process may differ from the amount of time that it takes to complete the cleaning process.

In this case, the amount by which unprocessed substrates W are moved simultaneously may differ from the amount by which processed substrates W are moved simultaneously, and the amount of simultaneous movement of the processed substrates W may be less than the amount of simultaneous movement of the unprocessed substrates W. To accommodate these variations, the first and robot arms 310a and 310b may include different numbers of transfer hands, as illustrated in FIGS. 11 and 12. FIGS. 11 and 12 are a side view and a front view, respectively, illustrating the arrangement of the robot arms and the transfer hands of the substrate transport robot according to a third exemplary embodiment of the present disclosure.

As previously mentioned, the substrate transport robot 210 may include multiple robot arms 310, each of which may include multiple transfer hands 320. The multiple robot arms 310 and the multiple transfer hands 320 may perform pick-and-place operations.

Among the multiple transfer hands 320, there may be some that are not used in the pick-and-place operations. The unused transfer hands 320 may rotate in a clockwise or counterclockwise direction for avoidance.

However, during an avoidance motion, collisions may occur between the edges of the transfer hands 320 and the inner walls of the index module (120) due to the rotation of the transfer hands 320, potentially leading to damage. Additionally, collisions may also occur between the edges of the transfer hands 320 and the load port modules 110, resulting in potential damage to the transfer hands 320.

To address the above and other issues, the size of the index module 120 may be expanded to secure additional space to accommodate the rotation of the transfer hands 320, which however, may lead to other problems, such as an increase in the overall size of the substrate processing system 100.

A method for avoiding interference between the substrate transport robot 210 and a structure (e.g., the load port modules 110 or the inner sidewalls of the index module 120) will hereinafter be described.

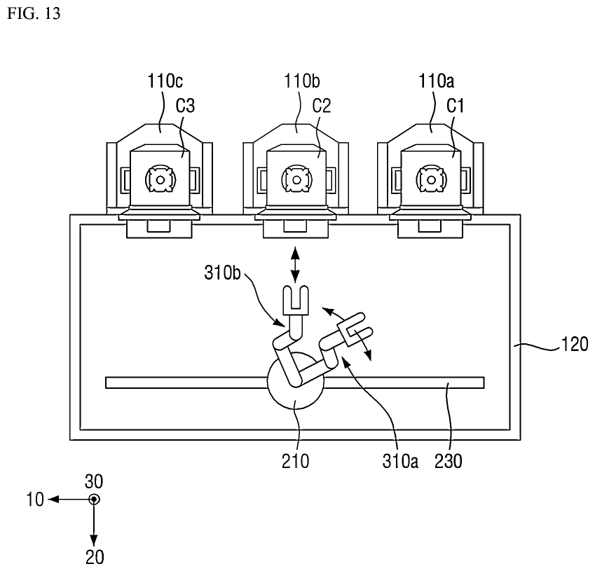

FIGS. 13, 14, and 15 are first, second, and third exemplary schematic views illustrating a method of avoiding interference between a structure and a substrate transport robot with multiple robot arms and multiple transfer hands.

Referring to FIGS. 13 through 15, the first robot arm 310a, which is included in the substrate transport robot 210, may include four transfer hands, i.e., first, second, third, and fourth transfer hands 320a, 320b, 320c, and 320d, and the second robot arm 310b, which is also included in the substrate transport robot 210, may also include four transfer hands, i.e., first, second, third, and fourth transfer hands 320a, 320b, 320c, and 320d. A case where the second, third, and fourth transfer hands 320b, 320c, and 320c of the first robot arm 310a are used for pick-and-place operations, while the first transfer hand 320a of the first robot arm 310a is not used for pick-and-place operations, will hereinafter be described as an example.

Referring to FIG. 13, when the first robot arm 310a of the substrate transport robot 210 retrieves semiconductor substrates W from the second container C2 on the second load port module 110b, the second, third, and fourth transfer hands 320b, 320c, and 320d of the first robot arm 310a, which are used for pick-and-place operations, may move forward to retrieve the semiconductor substrates W from the second container C2 on the second load port module 110b. On the other hand, the first transfer hand 320a of the first robot arm 310a, which is not used for pick-and-place operations, may rotate clockwise or counterclockwise to prevent collisions with the outer sidewalls of the second load port module 110b.

When the substrate transport robot 210 retrieves semiconductor substrates W from the second container C2, there is a significant distance between the substrate transport robot 210 and both inner sidewalls of the index module 120. Therefore, the first transfer hand 320a of the first robot arm 310a may perform a clockwise rotational movement to avoid collisions with the inner sidewalls of the index module 120. Alternatively, the first transfer hand 320a of the first robot arm 310a may perform a counterclockwise rotational movement to avoid collisions with the inner sidewalls of the index module 120.

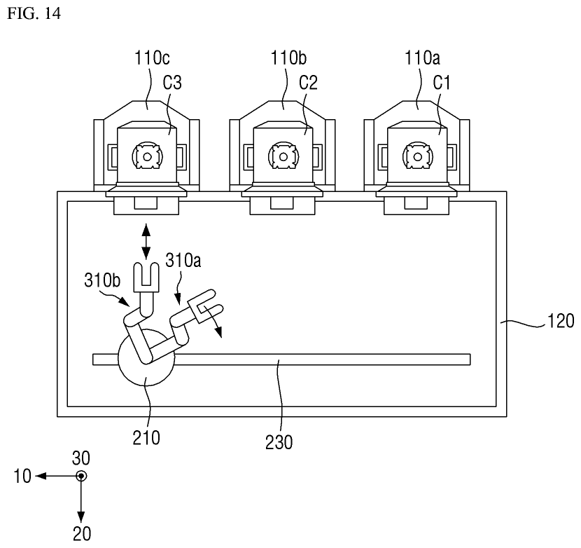

Referring to FIG. 14, when the first robot arm 310a of the substrate transport robot 210 retrieves semiconductor substrates W the third container C3 on the third load port module 110c, the second, third, and fourth transfer hands 320b, 320c, and 320d of the first robot arm 310a, which are used for pick-and-place operations, may move forward to retrieve the semiconductor substrates W from the third container C3 on the third load port module 110c. On the other hand, the first transfer hand 320a of the first robot arm 310a, which is not used for pick-and-place operations, may rotate clockwise to avoid collisions with the outer sidewalls of the third load port module 110c.

When the substrate transport robot 210 retrieves semiconductor substrates W from the third container C3, there is a significant distance between the substrate transport robot 210 and the right inner sidewall of the index module 120. Therefore, the first robot hand 320a may perform a clockwise rotational movement to avoid collisions with the inner sidewalls of the index module 120.

On the other hand, the substrate transport robot 210 may be very close to the left inner sidewall of the index module 120. In this case, if the first transfer hand 320a rotates counterclockwise, collisions may occur between the first transfer hand 320a and the inner sidewalls of the index module 120. Therefore, when the substrate transport robot 210 retrieves semiconductor substrates W from the third container C3, the first transfer hand 320a performs a clockwise rotational movement and does not rotate counterclockwise.

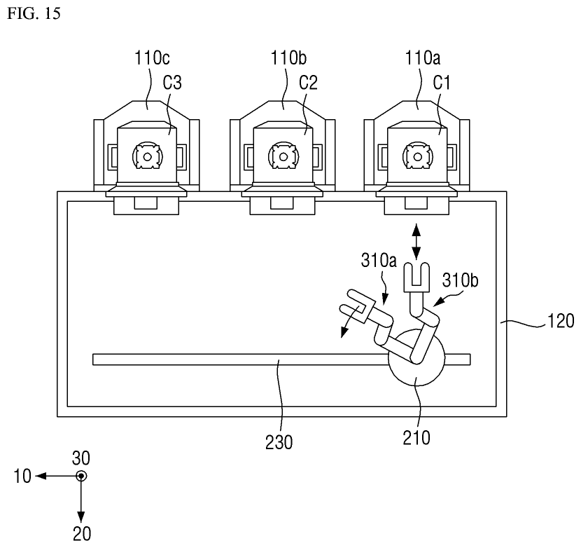

Referring to FIG. 15, when the first robot arm 310a of the substrate transport robot 210 retrieves semiconductor substrates W from the first container C1 on the first load port module 110a, the second, third, and fourth transfer hands 320b, 320c, and 320d, which are used for pick-and-place operations, may move forward to retrieve the semiconductor substrates W from the first container C1. On the other hand, the first transfer hand 320a, which is not used for pick-and-place operations, may perform a counterclockwise rotational movement to avoid collisions with the outer sidewalls of the first load port module 110a.

When the substrate transport robot 210 retrieves semiconductor substrates W from the first container C1, there is a significant distance between the substrate transport robot 210 and the left inner sidewall of the index module 120. Therefore, the first transfer hand 320a may perform a counterclockwise rotational movement to avoid collisions with the inner sidewalls of the index module 120.

On the other hand, the substrate transport robot 210 may be very close to the right inner sidewall of the index module 120. In this case, if the first transfer hand 320a rotates clockwise, collisions may occur between the first transfer hand 320a and the inner sidewalls of the index module 120. Therefore, when the substrate transport robot 210 retrieves semiconductor substrates W from the first container C1, the first transfer hand 320a rotates counterclockwise and does not rotate clockwise.

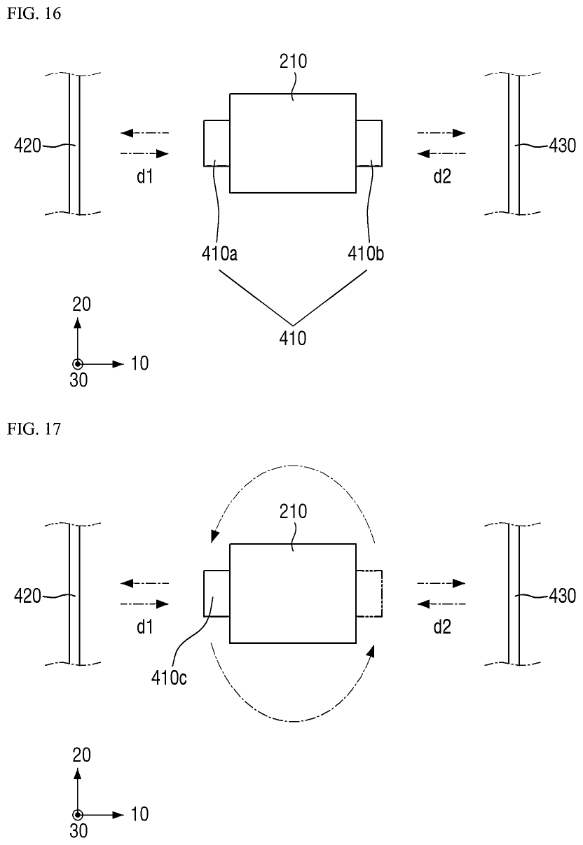

To determine the rotational movement direction of the first transfer hand 320a, the substrate transport robot 210 may further include an obstacle detection sensor. FIG. 16 is a first exemplary schematic view illustrating an obstacle detection method for a substrate transport robot with multiple robot arms and multiple transfer hands.

An obstacle detection sensor 410 is for determining whether the substrate transport robot 210 is adjacent to the inner sidewalls of the index module 120. For example, the obstacle detection sensor 410 may be provided as a distance measuring sensor capable of measuring distances.

The controller may determine, based on one measurement result from the obstacle detection sensor 410, whether the substrate transport robot 210 is adjacent to a left inner sidewall 420 of the index module 120. Moreover, the controller may determine, based on another measurement result from the obstacle detection sensor 410, whether the substrate transport robot 210 is adjacent to a right inner sidewall 430 of the index module 120.

The controller may determine whether the substrate transport robot 210 is adjacent to the left inner sidewall 420 of the index module 120 by comparing a measurement result d₁ from the obstacle detection sensor 410 with a reference value d_{ref}. If the measurement result d₁ is less than or equal to the reference value d_{ref} (i.e., d₁≤d_{ref}), the controller may determine that the substrate transport robot 210 is adjacent to the left inner sidewall 420 of the index module 120. If the measurement result d₁ is greater than the reference value d_{ref} (d₁>d_{ref}), the controller may determine that the substrate transport robot 210 is not adjacent to the left inner sidewall 420 of the index module 120.

Similarly, the controller may determine whether the substrate transport robot 210 is adjacent to the left inner sidewall 420 of the index module 120 by comparing a measurement result d₂ from the obstacle detection sensor 410 with the reference value d_{ref}. If the measurement result d₂ is less than or equal to the reference value d_{ref} (i.e., d₂≤d_{ref}), the controller may determine that the substrate transport robot 210 is adjacent to the right inner sidewall 430 of the index module 120. If the measurement result d₂ is greater than the reference value d_{ref} (d₂>d_{ref}), the controller may determine that the substrate transport robot 210 is not adjacent to the right inner sidewall 430 of the index module 120.

To enable the controller to determine the adjacency between the substrate transport robot 210 and the left and right inner sidewalls 420 and 430 of the index module 120, the obstacle detection sensor 410 may include two sensing modules, i.e., first and second sensing modules 410a and 410b. The first sensing module 410a may be installed on the left side of the substrate transport robot 210 and may be used to sense the left inner sidewall 420 of the index module 120. Similarly, the second sensing module 410b may be installed on the right side of the substrate transport robot 21) and may be used to sense the right inner sidewall 430 of the index module 120.

However, the present disclosure is not limited to this. Alternatively, referring to FIG. 17, the obstacle detection sensor 410 may include only one sensing module, i.e., a third sensing module 410c, and the third sensing module 410c may move back and forth between the left and right sides of the substrate transport robot 210 to sense both the left and right inner sidewall 420 and 430 of the index module 120. FIG. 17 is a second exemplary schematic view illustrating the obstacle detection method for the substrate transport robot with multiple robot arms and multiple transfer hands.

As described earlier, the first, second, and third sensing modules 410a, 410b, and 410c may be installed in the substrate transport robot 210. Specifically, the first and second sensing modules 410a and 410b may be installed on either side surface of each robot arm 310. Alternatively, the first and second sensing modules 410a and 410b may be installed on either side surface of the arm driving module 330. Alternatively, the first and second sensing modules 410a and 410b may be installed on either side surface of the rotation module 340. Alternatively, the first and second sensing modules 410a and 410b may be installed on either side surface of the vertical movement module 350. Alternatively, the first and second sensing modules 410a and 410b may be installed on either side surface of the horizontal movement module 360.

Similarly, the third sensing module 410c may be installed on either side surface of each robot arm 310. Alternatively, the third sensing module 410c may be installed on either side surface of the arm driving module 330. Alternatively, the third sensing module 410c may be installed on either side surface of the rotation module 340. Alternatively, the third sensing module 410c may be installed on either side surface of the vertical movement module 350. Alternatively, the third sensing module 410c may be installed on either side surface of the horizontal movement module 360.

The substrate transport robot 210, which is installed in the index module 120, particularly, the structure, functionality, and role of the first transport robot 210 have been described, and it should be noted that the substrate transport robot 220, which is installed in the transfer chamber 140, may also be installed and operated in the same manner as the substrate transport robot 210.

The present disclosure relates to the clean/dirty hand structure and avoidance motion operation of the substrate transport robot 210. The substrate transport robot 210 may be installed in the index module 120 of an EFEM and may be provided as an index SCARA robot. The present disclosure has been proposed in connection with the need to improve the processing speed of conventional substrate transfer robots, and the substrate transport robot 210 according to the present disclosure can have a structure that allows distinguishing between clean transfer hands for pre-processing and dirty transfer hands for post-processing during the pick-and-place of substrates. Additionally, the substrate transport robot 210 is capable of implementing and operating avoidance motions for collision prevention with the EFEM during its operation.

The substrate transport robot 210 may include two robot arms, i.e., the first and second robot arms 310a and 310b, to improve operation speed and distinguish between clean hands and dirty hands, and each of the first and second robot arms 310a and 310b may be configured with sets of multiple transfer hands 320 (i.e., second, third, and fourth transfer hands 320b, 320c, and 320d) and one transfer hand 320 (i.e., a first transfer hand 320a) that operates independently from the multiple transfer hands 320. The substrate transport robot 210 may perform each operation using the multiple transfer hands 320 or the single independent transfer hand 320 depending on the purpose.

The substrate transport robot 210 may divide the multiple transfer hands 320, located at the top or bottom of each of left and right robot arms 310 as clean hands for pre-processing and dirty hands for post-processing.

When only one transfer hand 320 is used to perform a pick-and-place operation, the other transfer hands 320 are unnecessary and thus can perform an avoidance motion, such as a clockwise or counterclockwise rotational motion. To prevent collisions with the load port modules 110 during the forward motion of the transfer hands 320 within the EFEM, the transfer hands 320 need to rotate in an appropriate direction such as either a clockwise or counterclockwise direction. For operations involving the third load port module 110c (e.g., when retrieving semiconductor substrates W from the third container C3 on the third load port module 110c), collisions with the sidewalls can be avoided through clockwise rotation of the transfer hands 320. For operations involving the first load port module 110a (e.g., when retrieving semiconductor substrates W from the first container C1 on the first load port module 110a), collisions with the sidewalls can be avoided through counterclockwise rotation of the transfer hands 320. For operations involving the second load port 110b (e.g., when retrieving semiconductor substrates W from the second container C2 on the second load port 110b), no collisions occur, and thus, the transfer hands 320 can rotate in both clockwise and counterclockwise directions. The substrate transport robot 210 may perform these operations to avoid interference/collisions with the load port modules 110 during the pick-and-place motion of the transfer hands 320 within the EFEM, particularly avoiding collisions with both sidewalls when operating at the first and third load port modules 110a and 110c.

Embodiments of the present disclosure have been described above with reference to the accompanying drawings, but the present disclosure is not limited thereto and may be implemented in various different forms. It will be understood that the present disclosure can be implemented in other specific forms without changing the technical spirit or gist of the present disclosure. Therefore, it should be understood that the embodiments set forth herein are illustrative in all respects and not limiting.

What is claimed is:

1. A substrate transport robot comprising:
one or more robot arms including transfer hands and transferring semiconductor substrates with the transfer hands;
an arm driving module coupled to each of the robot arms and controlling the movement of each of the robot arms; and
a horizontal/vertical movement module controlling the position movement of the arm driving module,
wherein
multiple robot arms are provided, and
multiple transfer hands are included in each of the multiple robot arms.

2. The substrate transport robot of claim 1, wherein the multiple robot arms are arranged in a height direction of the substrate transport robot.

3. The substrate transport robot of claim 1, wherein the multiple robot arms serve different purposes.

4. The substrate transport robot of claim 3, wherein the multiple robot arms are used to transport semiconductor substrates that have different processing statuses.

5. The substrate transport robot of claim 1, wherein the multiple transfer hands are arranged in a height direction of the substrate transport robot.

6. The substrate transport robot of claim 1, wherein the multiple transfer hands include a first transfer hand, which operates independently, and a plurality of transfer hands, which operate simultaneously.

7. The substrate transport robot of claim 6, wherein a robot arm with the plurality of transfer hands is disposed either above or below at least one other robot arm.

8. The substrate transport robot of claim 7, wherein
the first hand is disposed above the other transfer hands if the robot arm with the plurality of transfer hands is disposed above the at least one other robot arm.

9. The substrate transport robot of claim 7, wherein the first hand is disposed below the other transfer hands if the robot arm with the plurality of transfer hands is disposed below the at least one other robot arm.

10. The substrate transport robot of claim 1, wherein the number of transfer hands included in each of the multiple robot arms is the same.

11. The substrate transport robot of claim 1, wherein
a position of a single transfer hand that operates independently varies from one robot hand to another robot hand among the multiple transfer hands included in each of the multiple robot arms.

12. The substrate transport robot of claim 1, wherein the multiple transfer hands include transfer hands that are used in pick-and-place operations for the semiconductor substrates and transfer hands that are not used in the pick-and-place operations.

13. The substrate transport robot of claim 12, wherein the transfer hands not used in the pick-and-place operations rotate in at least one of clockwise and counterclockwise directions.

14. The substrate transport robot of claim 13, wherein distances from both sidewalls are considered when determining a rotation direction of the transfer hands not used in the pick-and-place operations.

15. The substrate transport robot of claim 1, further comprising:
a sensor measuring a distance between both sidewalls.

16. The substrate transport robot of claim 15, wherein the sensor is provided on either side of the substrate transport robot or is movably provided on one side of the substrate transport robot.

17. The substrate transport robot of claim 1, wherein the substrate transport robot is provided within a module that transfers semiconductor substrates between load port modules, on which containers loaded with a plurality of semiconductor substrates are mounted, and process chambers, in which the semiconductor substrates are processed.

18. A substrate transport robot comprising:
one or more robot arms including transfer hands and transferring semiconductor substrates with the transfer hands;
an arm driving module coupled to each of the robot arms and controlling the movement of each of the robot arms; and
a horizontal/vertical movement module controlling the position movement of the arm driving module,
wherein
multiple robot arms are provided,
multiple transfer hands are included in each of the multiple robot arms,
the multiple robot arms and the multiple transfer hands are arranged in a height direction of the substrate transport robot,
the multiple robot arms serve different purposes,
the multiple transfer hands include a first transfer hand, which operates independently, and a plurality of transfer hands, which operate simultaneously,
a position of a single transfer hand that operates independently varies from one robot hand to another robot hand among the multiple transfer hands included in each of the multiple robot arms,
the multiple transfer hands include transfer hands that are used in pick-and-place operations for the semiconductor substrates and transfer hands that are not used in the pick-and-place operations, and
the transfer hands not used in the pick-and-place operations rotate in at least one of clockwise and counterclockwise directions based on distances to both walls.

19. A substrate processing system comprising:
load port modules providing mounting surfaces for containers loaded with semi conductor substrates;
load lock chambers temporarily storing the semiconductor substrates and switching into one of an atmospheric environment and a vacuum environment depending on whether the semiconductor wafers are being loaded or unloaded;
process chambers processing the semiconductor substrates;
an index module operating at the atmospheric environment and transferring the semiconductor substrates between the load port modules and the load lock chambers; and
a transfer chamber operating at the vacuum environment and transferring the semiconductor substrates between the load lock chambers and the process chambers,
wherein
a substrate transport robot is provided within the index module and includes one or more robot arms, which include transfer arms and transfer the semiconductor substrates using the transfer hands, an arm driving module, which is coupled to each of the robot arms and controls the movement of each of the robot arms, and a horizontal/vertical movement module, which controls the position movement of the arm driving module,
multiple robot arms are provided, and
multiple transfer hands are included in each of the multiple robot arms.

20. The substrate treatment system of claim 19, wherein
the multiple robot arms are arranged in a height direction of the substrate transport robot, and
the multiple robot arms serve different purposes.
